(19) United States
(12) Patent Application Publication
(10) Pub. No.: US 2015/0293049 A1
(43) Pub. Date: Oct. 15, 2015

(54) Sensing Device and Method of Fabricating the Same

(71) Applicant: National Tsing Hua University, Hsinchu (TW)

(72) Inventors: Shalini JAYAKUMAR, Tamil Nadu (IN); Chi-Young LEE, Hsinchu (TW); I-Nan LIN, New Taipei City (TW)

(21) Appl. No.: 14/454,610

(22) Filed: Aug. 7, 2014

(30) Foreign Application Priority Data
Apr. 11, 2014 (TW) 103113369

(51) Int. Cl. G01N 27/327; H01L 21/02

(52) U.S. Cl. CPC G01N 27/327; H01L 21/02527; H01L 21/02491; H01L 21/02381

(57) ABSTRACT

The present invention provides a sensing device. The sensing device at least comprises a substrate, a layer of gold material and a layer of diamond nanowires, in which the layer of gold material is disposed on the substrate and the layer of diamond nanowires is disposed on the layer of gold material. A method of fabricating the abovementioned sensing device is also disclosed in the present invention.

This Non-provisional application claims priority under 35 U.S.C. §119(a) on Patent Application No(s).TW103113369 filed in 2014 Apr. 11, the entire contents of which are hereby incorporated by reference.

### BACKGROUND OF THE INVENTION

1. Field of the Invention

This invention relates to a sensing device and, more particularly, to a sensing device and a method of fabricating the same applied for sensing biotic factors and metal ions by combining diamond nanowires, gold and silicon.

2. Description of the Related Art

In the industries of the modern society, the heavy industry are progressed to high tech industry. Bio-medical and bio-technology getting more attention in nowadays are due to the focus of health and medicine for human beings. Because blood and urine are obtained easily from the body, the tiny change of physiology can be monitored in situ thus to further send a warning and give the therapy at the same time. More or less electrolyte concentration existing in blood and urine, such as Cl, K, Na, Ca and so on, may correlate to certain disease happening.

As a result, in order to monitor the concentration of these electrolytes, some sensors have been developed, such as ion-sensitive field effect transistors (ISFET), ion selective electrodes (ISE), electrolyte insulator semiconductors (EIS) and so on.

For example, there are more than one billion nerve cells in the brain which connect to each other by complicated nerve network and use chemical molecule to transfer the intermediate for information, in which Dopamine is an important neurotransmitter for controlling the function of the brain, such as actions, emotions, and high lever Cognition abilities.

The lack of dopamine concentration in the brain will lose the ability of controlling muscle. It may also cause Parkinson's disease in severity. On the contrary, the over high dopamine concentration may also cause hallucination, delusion, dysthesia and further obsessive-compulsive disorder (OCD) of the patients. For this reason, the concentration of dopamine is necessary to maintain in a normal range. Otherwise, it may result in the diseases as mentioned before.

However, since ISFET is not very sensitive, which has a detection range around 1 μM, and the dopamine concentration in the brain is lower, ISFET cannot measure the dopamine concentration changing correctly in the brain.

Moreover, as the generation progressing, modern people more care about health and medicine as well as issue of environment and food safety. However, as the technology developed, the pollution of heave metal is getting worst in the environmental contamination and the content thereof in food, cosmetic, natural product, animal and plant feed, and animal and plant product gradually becomes an important issue. Therefore, both consumers and detected institute require a high sensitive detector for all kinds of metal ions and more and more people join to the developing a detector for measure the heavy metal in the environment.

The methods to detect ions are included flame photometry, atomic absorption spectrometry, ion selective electrodes, electron microprobe, and neutron activation analysis. However, they all have the problems of the low sensitivities.

Moreover, whether the sensing device applied on bio-medical and bio-technology or the sensing device applied for detecting heavy metal ions. Most of the main material of the previous techniques is carbon or graphene.

### BRIEF SUMMARY OF THE INVENTION

According to abovementioned, the present invention provides a sensing device, which uses different material from the prior art, by combining diamond nanowires, gold (Au) and silicon (Si), and further, it can be modified by different coating layers for sensing biotic factors and metal ions and presenting high chemical stability and high efficiency in transporting electrons. Comparing to the conventional detecting method, the present invention can further distinguish expressions of different target substances clearly.

Therefore, the sensing device provided in the present invention at least comprises a substrate, layer of gold material and a layer of diamond nanowires. The layer of gold material is disposed on the substrate and the layer of diamond nanowires is disposed on the layer of gold material.

In an embodiment of the present invention, the substrate is a silicon substrate.

In an embodiment of the present invention, the sensing device provided in the present invention further comprises a modifying layer, in which the modifying layer is disposed on the layer of diamond nanowires for a target factor to be adhered on the sensing device. Preferably, the target factor is a biotic factor or a chemical factor.

In an embodiment of the present invention, the target factor is capable of being Dopamine, NADH, Urea, Nicotine or heavy metal ions.

In an embodiment of the present invention, the modifying layer is a samarium (III) hexacyanoferrate (III) (SmHCF) layer when the target factor is the heavy metal ions. Preferably, the heavy metal ions are capable of being Zn²⁺, Cd²⁺, Pb²⁺, Cu²⁺ or Hg²⁺.

In an embodiment of the present invention, the SmHCF layer comprises a plurality of flower-like surface structures.

In an embodiment of the present invention, the layer of diamond nanowires comprises a plurality of needle-like surface structures.

Another aspect of the present invention is to provide a method of fabricating a sensing device. The method at least comprises the following steps: First, a substrate is provided. A layer of gold material is formed on the substrate. And then, a layer of diamond nanowires is formed on the layer of gold material.

In an embodiment of the present invention, the step of forming the layer of diamond nanowires on the layer of gold material further comprises the following steps: First, the substrate with the layer of gold material formed thereon is placed into a first solution, in which the first solution comprises diamond powder and titanium powder. A plurality of nucleation sites is then formed on the layer of gold material and allowed to form the layer of diamond nanowires.

In an embodiment of the present invention, the diamond powder has a scale of 5 nm and the titanium powder has a scale of 37 mm in the step of placing the substrate with the layer of gold material formed thereon into a first solution.

In an embodiment of the present invention, the step of forming a plurality of nucleation sites is performed by ultrasonic vibration.

In an embodiment of the present invention, the step of allowing the nucleation sites to form the layer of diamond nanowires comprising the following steps: First, the substrate is placed into a mixed gas containing methane and nitrogen gas and the gas is excited by microwave to form a plasma state. The nucleation sites are allowed to form the layer of diamond nanowires on the substrate by a chemical vapor deposition. Preferably, methane and nitrogen gas have a mixture ratio of 6:94, the power of the microwave is 1200 W and the temperature of the substrate is 700° C.

In an embodiment of the present invention, the method provided in the present invention further comprises the following steps: First, the substrate with the layer of diamond nanowires formed thereon is placed into a second solution and then a modifying layer is formed on the layer of diamond nanowires.

In an embodiment of the present invention, the second solution comprises SmCl3, Fe(CF₆) and NaCl and the step of forming a modifying layer on the layer of diamond nanowires is performed by an electrochemical deposition.

In an embodiment of the present invention, the modifying layer is a samarium (III) hexacyanoferrate (III) (SmHCF) layer.

In an embodiment of the present invention, the substrate is a silicon substrate.

The features and advantages of the present invention will be understood and illustrated in the following specification and FIGS. 1˜7B.

### BRIEF DESCRIPTION OF THE DRAWINGS

FIG. 1 is a schematic drawing showing a sensing device according to a preferred embodiment of the present invention;

FIG. 2 is a flowchart showing a method of fabricating a sensing device according to a preferred embodiment of the present invention;

FIG. 3 is a cyclic voltammetry (CV) curve of depositing SmHCF on a layer of diamond nanowires according to the present invention;

FIG. 4A and FIG. 4B are SEM images showing the sensing device and the sensing device modified by SmHCF according to the present invention, respectively;

FIG. 5A and FIG. 5B are differential pulse voltammetry (DPV) curves measured by placing the sensing device of the present invention into a mixed solution containing a plurality of heavy metal ions;

FIG. 6 is a differential pulse voltammetry curve measured by placing the sensing device of the present invention in a solution containing a plurality of biotic factors; and

FIG. 7A and FIG. 7B are differential pulse voltammetry (DPV) curves measured by placing the sensing device of the present invention and placing a conventional boron-doped diamond (BDD) electrode into a solution containing a plurality of biotic factors.

### DETAILED DESCRIPTION OF THE INVENTION

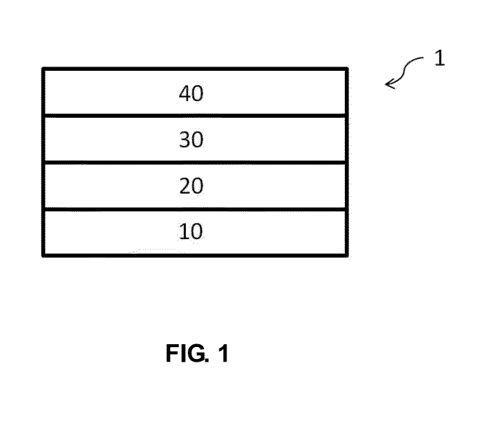

Accordingly, the present invention is to provide a sensing device capable of detecting biotic factors or heavy metal ions. Please refer to FIG. 1, FIG. 1 is a schematic drawing showing a sensing device according to a preferred embodiment of the present invention. As shown in the figure, the sensing device 1 provided in the present invention at least comprises a substrate 10, a layer of gold material 20 and a layer of diamond nanowires 30, in which the layer of gold material 20 is disposed on the substrate 10 and the layer of diamond nanowires 30 is disposed on the layer of gold material 20. Preferably, the substrate 10 is a silicon substrate.

Furthermore, in a preferred embodiment of the present invention, the sensing device 1 provided in the present invention further comprises a modifying layer 40 disposed on the layer of diamond nanowires 30 as shown in FIG. 1 for a target factor to be adhered on the sensing device 1.

Preferably, the sensing device 1 provided in the present invention can be applied on different factors to be tested according to the types of the modifying layer 40. Thus, the target factor can be a biotic factor, such as Dopamine, NADH, Urea or Nicotine. Moreover, the modifying layer 40 can be a samarium (III) hexacyanoferrate (III) (SmHCF) layer if the target factor is a chemical factor, such as heavy metal ions (Zn²⁺, Cd²⁺, Pb²⁺, Cu²⁺ or Hg²⁺).

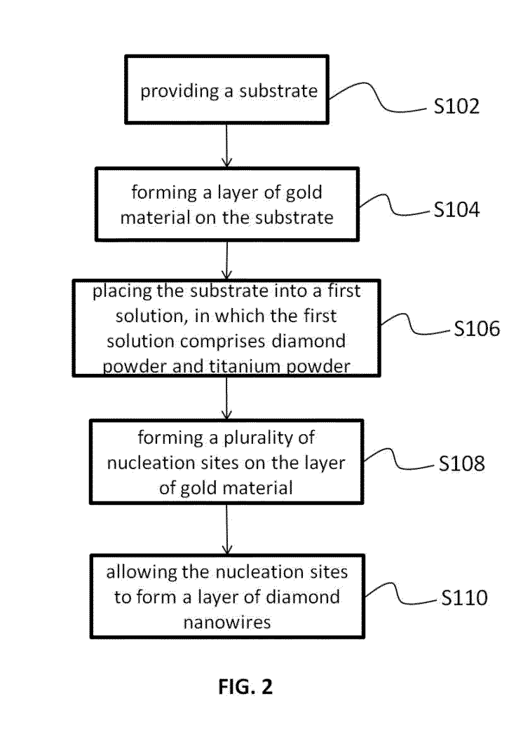

Another aspect of the present invention is to provide a method of fabricating the abovementioned sensing device 1. Please refer to FIG. 2, which is a flowchart showing a method of fabricating a sensing device according to a preferred embodiment of the present invention. First, a substrate is provided in step S102 and preferably the substrate as mentioned above is a silicon substrate. As shown in step S104, a layer of gold material is then formed on the substrate.

And then, the substrate with the layer of gold material formed thereon is placed into a first solution as shown in step S106. The first solution is a methanol solution comprising diamond powder and titanium powder. Preferably, the diamond powder has a scale of 5 nm and the titanium powder has a scale of. An ultrasonic vibration is then performed (preferably for 45 minutes, however, the present invention is not limited thereto) to allow a plurality of nucleation sites to be formed on the surface of the layer of gold material as shown in step S108. The nucleation sites are finally allowed to form a layer of diamond nanowires as shown in step S110.

In the preferred embodiment, the abovementioned step S110 at least comprises the following steps even though they are not shown in the figure. The substrate is placed into a mixed gas comprising methane and nitrogen gas at first, and the gas is excited by microwave to form a plasma state. And then, the nucleation sites are allowed to form the layer of diamond nanowires on the substrate by a chemical vapor deposition. Preferably, in the abovementioned steps, the layer of diamond nanowires is obtained under an environment adopting process parameters, in which methane and nitrogen gas have a mixture ratio of 6:94, the power of the microwave is 1200 W and the temperature of the substrate is 700° C., for 30 minutes of growth. However, the present invention is not limited thereto.

Similarly, the method of fabricating the sensing device provided in the present invention further comprises the following steps for sensing the biotic factors or the chemical factors even though they are not shown in the figure. First, the substrate with the layer of diamond nanowires formed thereon is placed into a second solution. A modifying layer is then formed on the layer of diamond nanowires. Preferably, as mentioned above, the modifying layer 40 can be a samarium (III) hexacyanoferrate (III) (SmHCF) layer if the target factor is a heavy metal ion, such as Zn²⁺, Cd²⁺, Pb²⁺, Cu²⁺ or Hg²⁺. At that time, the second solution correspondingly comprises SmCl₃, Fe(CF₆) and NaCl, and preferably, a mixed solution comprising 5 mM SmCl₃, 5 mM K₃Fe(CN)₆ and 0.2 mM NaCl. In the present invention, these chemicals are samarium trichloride hydrate (99%), K₃Fe(CN)₆ and NaCl which are purchased from Sigma-Aldrich Aldrich chemicals and used without further purification. In addition, the abovementioned step of forming the modifying layer on the layer of diamond nanowires is performed by an electrochemical deposition. However, the present invention is not limited thereto.

After the description of the structure of the sensing device provided in the present invention and the method of fabricating the same, the SmHCF layer is taken as an example for illustrating the test and the results of testing the heavy metal ions.

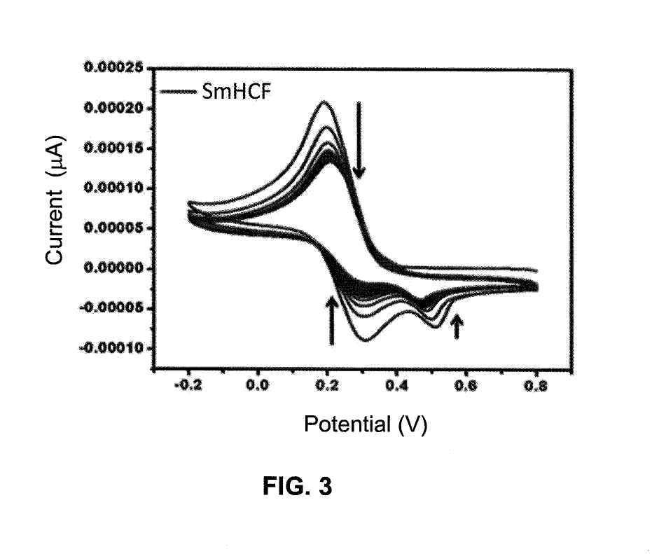

Please refer to FIG. 3, which is a cyclic voltammetry (CV) curve of depositing SmHCF on a layer of diamond nanowires according to the present invention. The electrochemical property of the sensing device provided in the present invention is characterized using cyclic voltammetry (CV, Autolab PGSTAT302, Netherlands). A standard three electrode cell was employed. In details, the layer of diamond nanowires, which is grown under a substrate temperature of 700° C., is used as the working electrode (working area of 0.186 cm2). A platinum (Pt) rod and silver/silver chloride (Ag/AgCl) electrodes are served as the counter and reference electrodes respectively. The electrolyte is acetic buffer solution (ABS, pH=4.5), and all the measurements are carried out at room temperature. When the SmHCF layer is deposited to the surface of the layer of diamond nanowires, the used scan potential is −0.2˜30 0.8V, the scan rate is 50 mV/s and the scan cycle is 20 cycles. As shown in the figure, the SmHCF layer is found to be formed on the surface of the layer of diamond nanowires during each cycle of the measurement and it can be observed from the changes of the current peaks of different cycles. In details, the mechanism of the electrochemical reaction of SmHCF is described as the following:

Fe(CN)₆³⁻+e⁻→Fe(CN)₆^{4″}(Electrochemical reaction) (1)

Fe(CN)₆⁴⁻+Sm³⁺+Na⁺+nH₂O→NaSmFe(CN)₆.nH₂O (Chemical reaction) (2)

That is, in FIG. 3, a decrease of the current of the redox peak with an increase of the scan cycle corresponds to the redox of Fe (CN)₆^{3-/4-} and it denotes that the SmHCF layer is deposited on the surface of the layer of diamond nanowires.

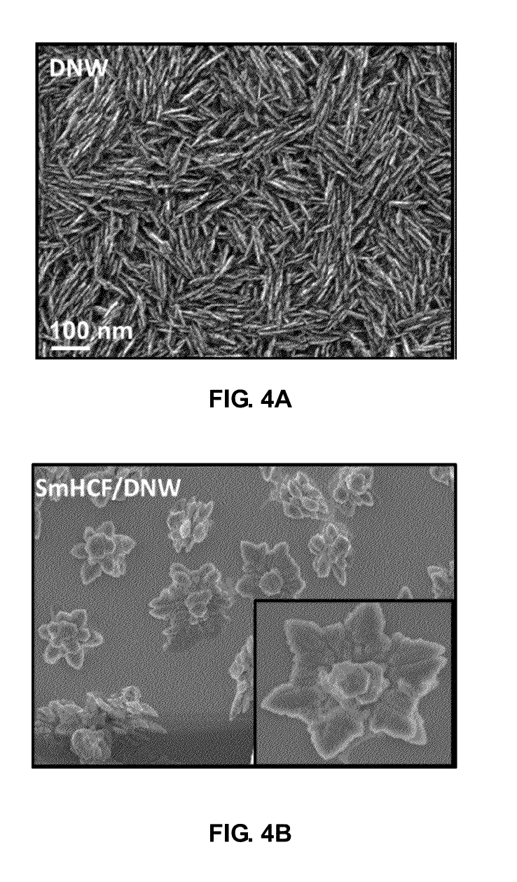

Accordingly, please refer to FIG. 4A and FIG. 4B. FIG. 4A and FIG. 4B are SEM images showing the sensing device and the sensing device modified by SmHCF according to the present invention, respectively. As shown in FIG. 4A, the layer of diamond nanowires, which is grown under MPECVD, comprises a plurality of needle-like surface structures. The SmHCF layer, which is deposited on the surface of the layer of diamond nanowires, comprises a plurality of flower-like surface structures. Preferably, the flower-like surface structures are dispersed on the surface of the layer of diamond nanowires and do not form a film.

The sensing device modified by the SmHCF layer/the layer of diamond nanowires is eventually washed using deionized water and then placed into a solution containing heavy metal ions for further application on electrochemical sensation. In this case, the solution containing heavy metal ions is a mixed solution fabricated in acetic buffer solution (pH=4.5) and comprising single component (Pb²⁺, Cd²⁺, Cu²⁺, Zn²⁺, Hg²⁺).

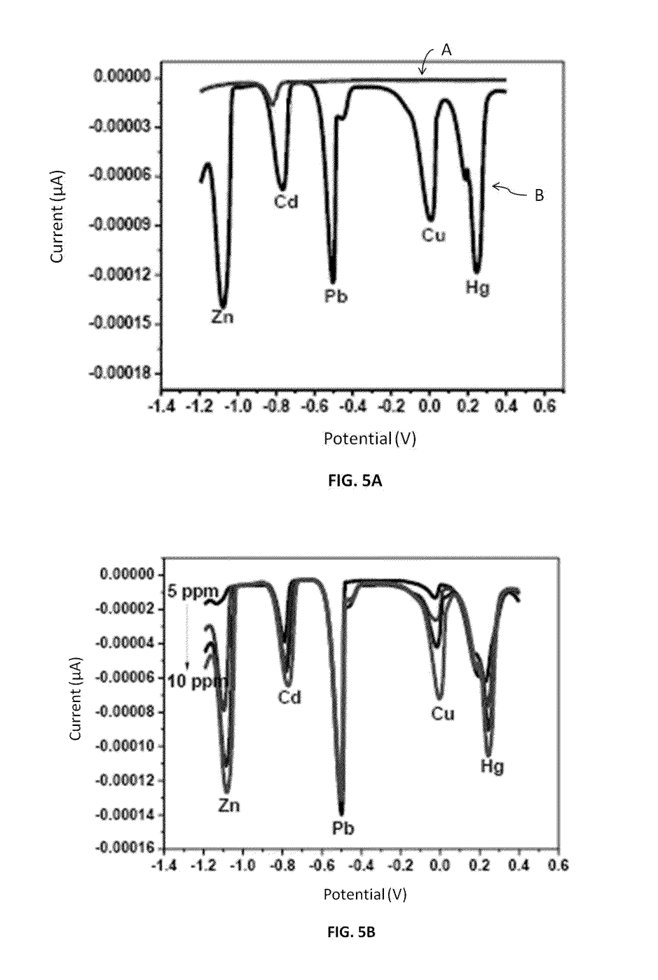

Please refer to FIG. 5A and FIG. 5B. FIG. 5A and FIG. 5B are differential pulse voltammetry (DPV) curves measured by placing the sensing device of the present invention into a mixed solution containing 10 ppm Zn²⁺, 10 ppm Cd²⁺, 10 ppm Pb²⁺, 10 ppm Cu²⁺ and 10 ppm Hg²⁺, in which the oxidation peaks for Zn²⁺, Cd²⁺, Pb²⁺, Cu²⁺ and Hg²⁺ are located, respectively, at −1.12V, −0.74V, −0.45V, +0.01V and +0.23V. And further, the peak separations of Zn²⁺—Cd²⁺, Cd²⁺—Pb²⁺, Pb²⁺—Cu²⁺, Cu²⁺—Hg²⁺and Zn²⁺—Hg²⁺ also can be observed in FIG. 5A and FIG. 5B so that it demonstrates the sensing device of the present invention can sensitively detect different heavy metal ions in the mixed solution.

Moreover, as shown in the figure, the oxidation current of Cd²⁺, Cu²⁺ and Hg²⁺ increases with an increase of Cd²⁺, Cu²⁺ and Hg²⁺ concentration. However, the increase of the oxidation current slows down when the concentration is over 50 mM. On the contrary, the oxidation current of Cd²⁺, Cu²⁺ and Hg²⁺ is linear and proportional to the concentration of that when the concentration is low (0.5˜10 mM).

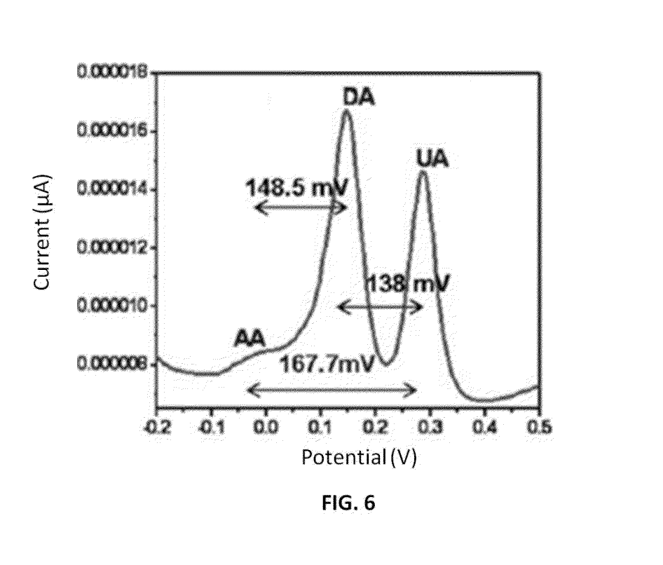

In addition to the abovementioned preferred embodiment, the sensing device also can be applied to the detection of biotic factors, such as Dopamine, NADH, Urea and Nicotine. Please refer to FIG. 6, Dopamine is taken as an example therein. FIG. 6 is a differential pulse voltammetry curve measured by placing the sensing device of the present invention, which is fabricated under a substrate temperature of 700° C., into a mixed solution containing 0.33 mM ascorbic acid (AA), 0.033 mM Dopamine (DA) and 0.033 mM uric acid (UA). As shown in the figure, the peak potentials at +0.0 V, +0.15 V and 0.28 V are due to the electro-oxidation of AA, DA and UA, respectively. And then, the peak separations of AA-DA, DA-UA, and AA-UA (148.5, 138, 286.1 mV), are also shown in the figure, which indicates that the sensing device of the present invention is highly sensitive towards the DA detection in the mixed solution.

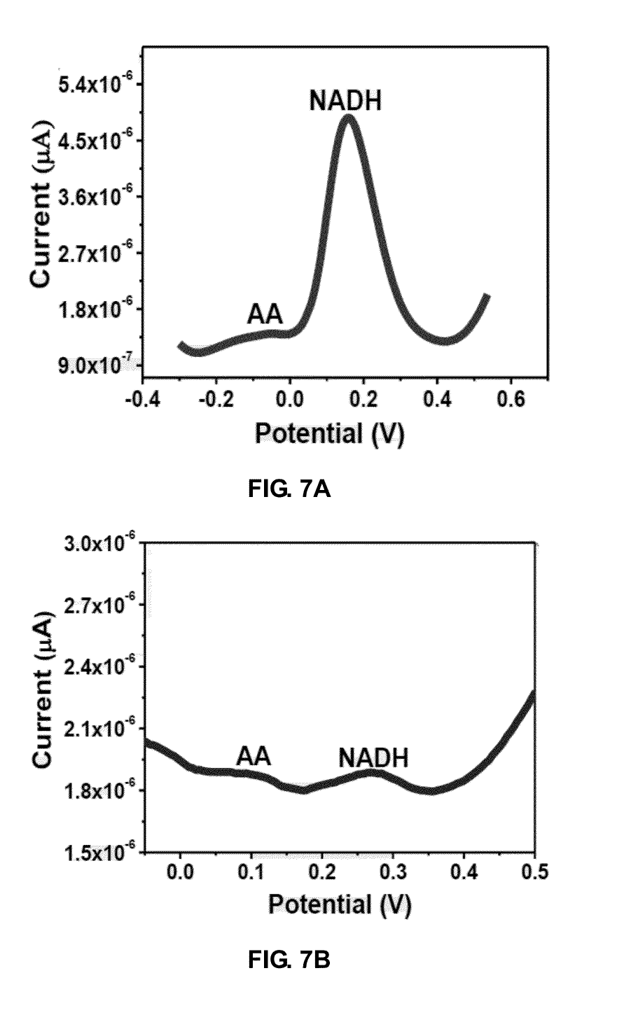

As shown in FIG. 7A and FIG. 7B, NADH is then taken as an example. FIG. 7A and FIG. 7B are differential pulse voltammetry (DPV) curves measured by placing the sensing device of the present invention and placing a conventional boron-doped diamond (BDD) electrode in a solution containing 0.33 mM AA+0.033 mM NADH (Pulse time=70 ms, pulse amplitude=50 mV). As shown in FIG. 7A, the peak at +0.0 V is due to the electrooxidation of AA along with the NADH signal at +0.15 V, this equates to a peak separation of 150 mV for the N-DNW electrode, which indicates that the N-DNW is highly sensitive towards NADH detection in the mixed solution. Comparing to the sensing device of the present invention, the peaks for AA and NADH are not well resolved when the BDD electrode was used as shown in FIG. 7B.

To sum up, the present invention provides a sensing device, which uses different material from the prior art, by combining diamond nanowires, gold (Au) and silicon (Si), and further, it can be modified by different coating layers for sensing biotic factors and metal ions and presenting high chemical stability and high efficiency in transporting electrons. Comparing to the conventional detecting method, the present invention can further distinguish expressions of different target substances clearly.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A sensing device, at least comprising:
a substrate;
a layer of gold material disposed on the substrate; and
a layer of diamond nanowires disposed on the layer of gold material.

2. The sensing device according to claim 1, wherein the substrate is a silicon substrate.

3. The sensing device according to claim 1, further comprising:
a modifying layer disposed on the layer of diamond nanowires for a target factor to be adhered on the sensing device, wherein the target factor is a biotic factor or a chemical factor.

4. The sensing device according to claim 3, wherein the target factor is capable of being Dopamine, NADH, Urea, Nicotine or heavy metal ions.

5. The sensing device according to claim 4, wherein the modifying layer is a samarium (III) hexacyanoferrate (III) (SmHCF) layer when the target factor is the heavy metal ions.

6. The sensing device according to claim 5, wherein the heavy metal ions are capable of being Zn²⁺, Cd²⁺, Pb²⁺, Cu²⁺ or Hg²⁺.

7. The sensing device according to claim 5, wherein the SmHCF layer comprises a plurality of flower-like surface structures.

8. The sensing device according to claim 1, wherein the layer of diamond nanowires comprises a plurality of needle-like surface structures.

9. A method of fabricating a sensing device, at least comprising the following steps:
providing a substrate;
forming a layer of gold material on the substrate; and
forming a layer of diamond nanowires on the layer of gold material.

10. The method according to claim 9, wherein the step of forming the layer of diamond nanowires on the layer of gold material further comprises the following steps:
placing the substrate with the layer of gold material formed thereon into a first solution, wherein the first solution comprises diamond powder and titanium powder;
forming a plurality of nucleation sites; and
allowing the nucleation sites to form the layer of diamond nanowires.

11. The method according to claim 10, wherein the diamond powder has a scale of 5 nm and the titanium powder has a scale of 37 mm in the step of placing the substrate with the layer of gold material formed thereon into a first solution.

12. The method according to claim 10, wherein the step of forming a plurality of nucleation sites is performed by ultrasonic vibration.

13. The method according to claim 10, wherein the step of allowing the nucleation sites to form the layer of diamond nanowires comprising the following steps:
placing the substrate into a mixed gas containing methane and nitrogen gas;
exciting the gas by microwave to form a plasma state; and
allowing the nucleation sites to form the layer of diamond nanowires on the substrate by a chemical vapor deposition.

14. The method according to claim 13, wherein methane and nitrogen gas have a mixture ratio of 6:94, the power of the microwave is 1200 W and the temperature of the substrate is 700° C.

15. The method according to claim 9, further comprising the following steps:
placing the substrate with the layer of diamond nanowires formed thereon into a second solution; and
forming a modifying layer on the layer of diamond nanowires.

16. The method according to claim 15, wherein the second solution comprises SmCl₃, Fe(CF₆) and NaCl and the step of forming a modifying layer on the layer of diamond nanowires is performed by an electrochemical deposition.

17. The method according to claim 16, wherein the modifying layer is a samarium (III) hexacyanoferrate (III) (SmHCF) layer.

18. The method according to claim 9, wherein the substrate is a silicon substrate.
